(19) United States
(12) Patent Application Publication
(10) Pub. No.: US 2009/0166058 A1
(43) Pub. Date: Jul. 2, 2009

(54) PRINTED CIRCUIT BOARD

(75) Inventors: YING-TSO LAI, Tu-Cheng (TW); YU-CHANG PAI, Tu-Cheng (TW); SHOU-KUO HSU, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/042,348

(22) Filed: Mar. 5, 2008

(30) Foreign Application Priority Data
Dec. 26, 2007 (CN) 200710203419.7

(51) Int. Cl. H05K 1/00

(52) U.S. Cl. 174/250

(57) ABSTRACT

A printed circuit board (PCB) includes a power layer having a base portion, and at least two extending portions. The at least two extending portions are extended from edges near at least one corner of the base portion for preventing the PCB from forming constructive interferences and lowering the resonance magnitude thereof.

### BACKGROUND

1. Field of the Invention

The present invention relates to printed circuit boards (PCBs), and particularly to a PCB which can reduce electro magnetic interference (EMI) therein.

2. Description of Related Art

Multilayer PCBs are commonly used in electronic devices to connect electronic components such as integrated circuits to one another. A typical multilayer PCB includes a power layer, a signal layer, and a ground layer. Generally, when the multilayer PCB works, some noise signals will transmit in the power layer of the PCB in electromagnetic wave mode, and the incident electromagnetic waves propagate toward the plane edges of the power layer and part of the energy reflects back, and then the reflected electromagnetic waves superpose with the incident electromagnetic waves together and form constructive interference.

Referring to FIGS. 6-8, a schematic view of electromagnetic wave at or near edges of a power layer of a conventional PCB is shown. There are two electromagnetic waves 2 and 4 transmitted therein, which have same frequency. The arrowhead A denotes the path of the electromagnetic waves 2 and 4. When the electromagnetic waves 2 and 4 reach the edges of the PCB, two reflected electromagnetic waves 6 and 8 will superpose with the incident electromagnetic waves 2 and 4 and form constructive interference (shown in FIG. 8). Therefore, the system energy concentrates on certain resonant spots, and the gathering of the reflection energy becomes another radiation source, which deteriorates the system radiation and may bring electro magnetic interference (EMI).

What is needed, therefore, is a PCB which can reduce constructive interference and EMI therein.

### SUMMARY

An embodiment of a printed circuit board (PCB) includes a power layer having a base portion, and at least two extending portions. The at least two extending portions are extended from edges near at least one corner of the base portion for preventing the PCB from forming constructive interference and lowering the resonance magnitude thereof.

Other advantages and novel features of the present invention will become more apparent from the following detailed description of an embodiment when taken in conjunction with the accompanying drawings, in which:

### BRIEF DESCRIPTION OF THE DRAWINGS

FIG. 1 is a schematic view of a PCB in accordance with an embodiment of the present invention;

FIG. 2 is a schematic view showing incident electromagnetic waves transmitting toward edges of a power layer of the PCB of FIG. 1;

FIG. 3 is a schematic view showing reflected electromagnetic waves of FIG. 2;

FIG. 4 is a schematic view showing overlap of the reflected electromagnetic waves of FIG. 3 together with the incident electromagnetic waves of FIG. 2;

FIG. 5 is a graph comparing radiation formed by different sizes of conventional PCBs and PCBs of the present invention;

FIG. 6 is a schematic view of incident electromagnetic waves transmitting toward edges of a power layer of a conventional PCB;

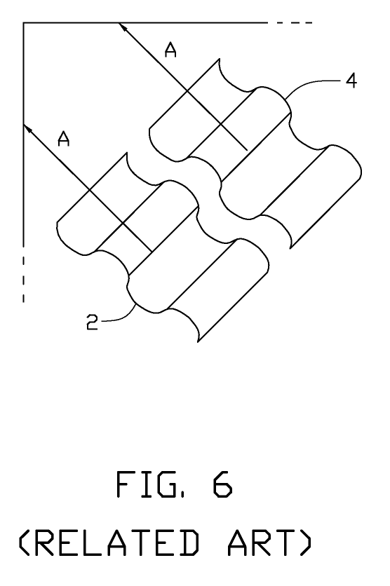

FIG. 7 is a schematic view of reflected electromagnetic waves of FIG. 6; and

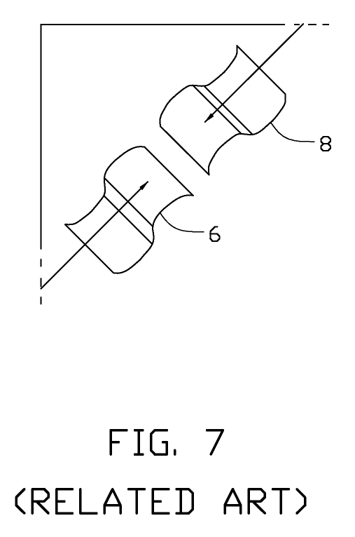

FIG. 8 is a schematic view showing overlap of the reflected electromagnetic waves of FIG. 7 together with the incident electromagnetic waves of FIG. 6.

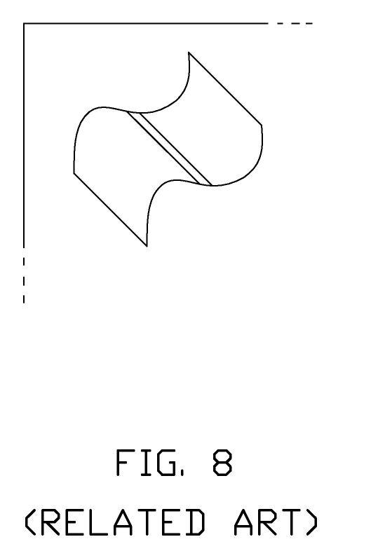

### DETAILED DESCRIPTION

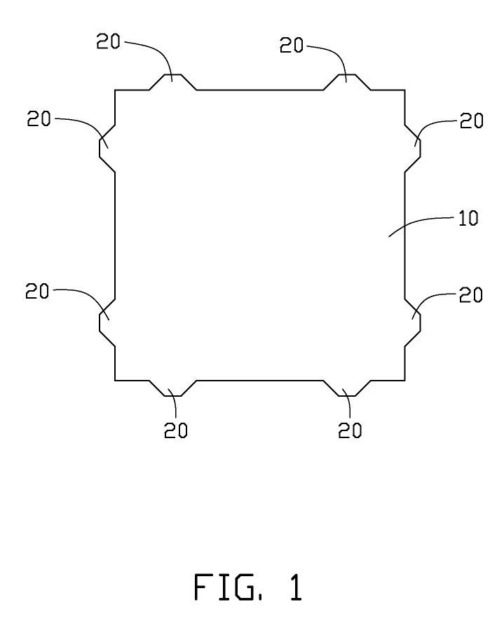

Referring to FIG. 1, a PCB in accordance with an embodiment of the present invention includes a power layer, a ground layer, and at least one signal layer. The power layer includes a base portion 10 and eight extending portions 20. The base portion 10 is rectangular. Each extending portion 20 is trapeziform and extends from an edge near a corresponding corner of the base portion 10. The shape of the ground layer and the at least one signal layer are the same as the power layer.

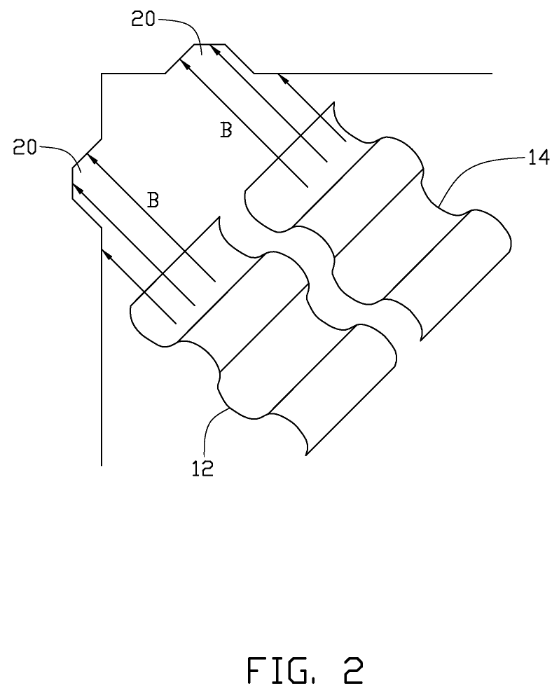

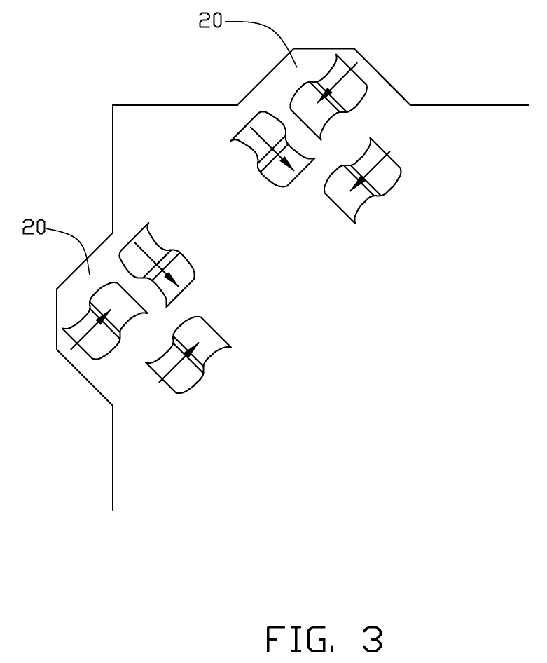

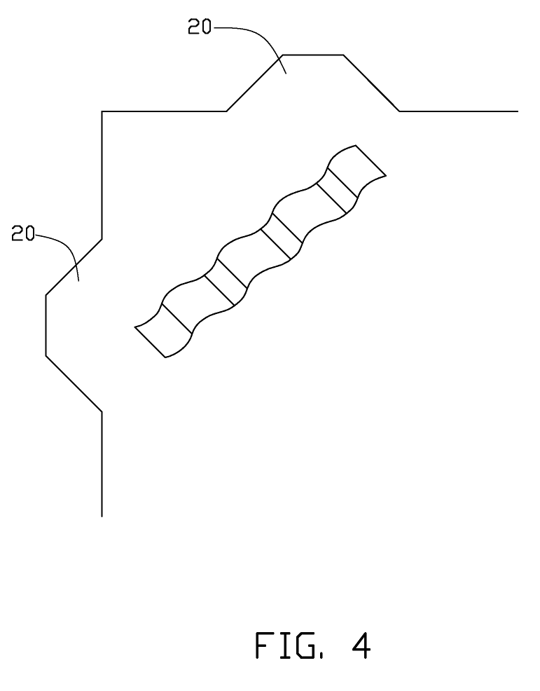

Referring also to FIGS. 2-4, some noise signals will transmit in the power layer of the PCB in electromagnetic wave mode, such as two electromagnetic waves 12 and 14 having the same frequency, transmitted in the power layer. The arrowhead B denotes the transmitting path of the electromagnetic waves 12 and 14. When the electromagnetic waves 12 and 14 are transmitted to the edges of the power layer, reflected path of the electromagnetic waves 12 and 14 are changed by the eight extending portions 20, thereby formation of constructive interference thereof will be prevented or minimized.

Advantageously, the ratios of the length and the width of the base portion 10, and the upper hemline, the lower hemline, and the height of each extending portion 20 can be 50:30:6:12:5, in this embodiment the length and the width of the base portion 10 are respectively 50 cm and 30 cm, and the upper hemline, the lower hemline, and the height of each extending portion 20 are respectively 6 cm, 12 cm and 5 cm. The size of the base portion 10 and the extending portions 20 can be changed according to need and the ratio relationship.

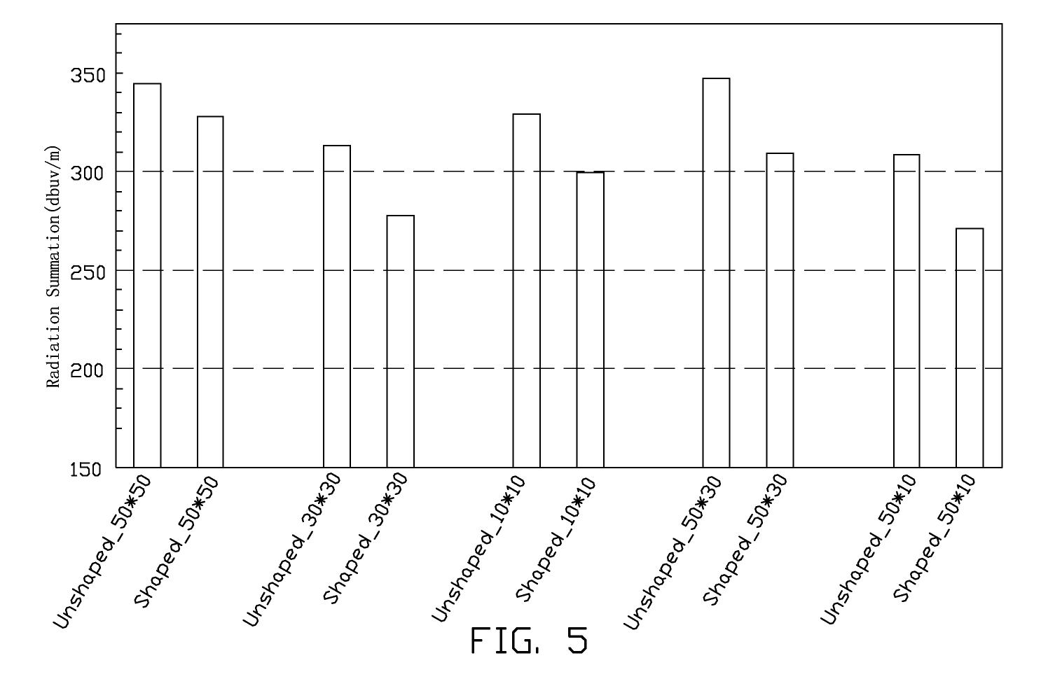

Referring also to FIG. 5, a graph comparing radiation formed by different sized conventional PCBs and PCBs of the present invention is shown. In the graph, conventional PCBs are designated as ‘unshaped’ followed by a number indicating length (l) and width (w) thereof in centimeters (cm). Similarly, a PCB in accordance with an embodiment of the present invention is designated as ‘shaped’ followed by a number indicating l and w thereof. For example, “Unshaped_{—}50*50” denotes a conventional PCB whose l and w is 50 cm*50 cm, and “shaped_{—}50*50” denotes a PCB in accordance with an embodiment of the present invention whose l and w is 50 cm*50 cm.

In FIG. 5, the radiation summation of each PCB in accordance with an embodiment of the present invention is lower then the corresponding size of the conventional PCB, namely the shaped PCB of the present invention can effectively reduce EMI thereof, and can prevent the PCB from forming constructive interference and lower the resonance magnitude, and can alleviate system radiation without additional cost. In other embodiments, the shape of the extending portions 20 can be triangle, polygon, hemicycle, and so on.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board (PCB) comprising:
a power layer having a base portion; and
at least two extending portions extended from edges near at least one corner of the base portion for preventing the PCB from forming constructive interferences and lowering the resonance magnitude thereof.

2. The PCB as claimed in claim 1, further comprising a ground layer and at least one signal layer, wherein the shape of the ground layer and the at least one signal layer are the same as the power layer.

3. The PCB as claimed in claim 1, wherein each of the at least two extending portions is triangular.

4. The PCB as claimed in claim 1, wherein each of the at least two extending portions is trapeziform, the base portion is a rectangle, two extending portions are extended from each corner of the base portion.

5. The PCB as claimed in claim 4, wherein the ratio of the length and the width of the base portion, and the upper hemline, the lower hemline, and the height of each of the at least two extending portion are 50:30:6:12:5.

6. The PCB as claimed in claim 1, wherein each of the at least two extending portions is trapeziform, the base portion is a square, two extending portions are extended from each corner of the base portion.

7. The PCB as claimed in claim 6, wherein the ratio of the hemline of the base portion, and the upper hemline, the lower hemline, and the height of each of the at least two extending portions are 50:6:12:5.

8. A generally rectangular printed circuit board (PCB) comprising:
Four edges, each of the edges having at least one non-straight portion in the vicinity of a corner of the PCB to reflect electromagnetic wave of noise waves in a power layer of the PCB in different directions, so that a summation amount of reflected electromagnetic wave of noise waves is reduced.

9. The PCB as claimed in claim 8, further comprising a ground layer and at least one signal layer, wherein the shape of the ground layer and the at least one signal layer are the same as the power layer.

10. The PCB as claimed in claim 8, wherein each of the at least one non-straight portion is triangular.

11. The PCB as claimed in claim 8, wherein each of the at least one non-straight portion is trapeziform.

12. The PCB as claimed in claim 11, wherein two non-straight portions are extended from each corner of the base portion, the ratio of the length and the width of the base portion, and the upper hemline, the lower hemline, and the height of each of the non-straight portions are 50:30:6:12:5.
